(19) United States
(12) Patent Application Publication
(10) Pub. No.: US 2016/0365463 A1
(43) Pub. Date: Dec. 15, 2016

(54) IR PHOTODETECTOR USING METAMATERIAL-BASED ON AN ANTIREFLECTION COATING TO MATCH THE IMPEDANCE BETWEEN AIR AND SP RESONATOR

(71) Applicant: Korea Research Institute of Standards and Science, Daejeon (KR)

(72) Inventors: Sang-Jun Lee, Daejeon (KR); Sang-Woo Kang, Daejeon (KR); Jun-Oh Kim, Gyeonggi-do (KR)

(21) Appl. No.: 14/826,708

(22) Filed: Aug. 14, 2015

(30) Foreign Application Priority Data
Jun. 15, 2015 (KR) 10-2015-0084502

(51) Int. Cl. H01L 31/0216; H01L 31/0304; H01L 31/0352; H01L 31/109; H01L 31/18

(52) U.S. Cl. CPC H01L 31/02161; H01L 31/109; H01L 31/184; H01L 31/035218; H01L 31/1844; H01L 31/03046

(57) ABSTRACT

Provided are an infrared photodetector and a method for manufacturing the same. The infrared photodetector includes a bottom contact layer, a light absorption layer stacked on the bottom contact layer, a top contact layer stacked on the light absorption layer, a metal layer stacked on the top contact layer to induce surface plasmon resonance and having a plurality of holes, and a dielectric layer stacked on the metal layer to satisfy an antireflection condition with respect to externally impinging light at a surface plasmon resonance frequency. The dielectric layer is a benzocyclobutene (BCB) layer.

### CROSS-REFERENCE TO RELATED APPLICATION

This U.S. non-provisional application is a continuation of and claims priority under 35 U.S.C.§119 to Korea Patent Application No. 10-2015-0084502 filed on Jun. 15, 2015, the entirety of which is hereby incorporated by reference.

### BACKGROUND

1. Technical Field

The present disclosure generally relates to infrared (IR) photodetectors and, more particularly, to an IR detector including a metal film having a metal hole array and an antireflective locating layer.

2. Description of the Related Art

An infrared (IR) detector has been mainly used in a military camera or a security camera but has been used recently as a vehicle camera. IR detectors are classified into thermal detectors and photon detectors.

A photon detector detects an electrical signal obtained when infrared impinging on a semiconductor material excites electrons inside the material, has high response speed and high detectability, and has wavelength-dependence of sensibility.

The important parameters of infrared detectors vary depending on applications but include quantum efficiency, dark current, and spectral bandwidth.

Typical semiconductor photodetectors (InSb, HgCdTe, InAs/GaAs), quantum well infrared photodetectors (QWIPs), InAs/GaAs quantum dot infrared photodetectors (QDIPs), and InAs/GaSb superlattice photodetectors may have relatively broad spectral bandwidths.

QWIPs and QDIPs typically have relatively low quantum efficiencies. Accordingly, surface plasmon methods have been studied to enhance quantum efficiencies in QDIPs and QDIPs.

Surface plasmon (SP) is a unique phenomenon that arises at the interface between a dielectric film and a metal thin film due to collective vibration of electrons. Light of a specific wavelength is not regularly reflected, and a surface wave propagating along the interface is called the surface plasmon. As it has been known that when incident light and surface plasmon match in phase, resonance occurs to modulate properties of a device, basic and application researches have been vigorously conducted in recent years. When a metal thin film with a periodical pattern such as a hole is formed on a dielectric or semiconductor surface, surface plasmon may arise. It has been reported that when surface plasmon was applied to a light emitting diode (LED), light-emitting efficiency was enhanced. When the surface plasmon is applied to an infrared detector, wavelength selectivity and light-receiving efficiency are improved at the same time. A resonance wavelength of a plasmon structure having a periodical hole pattern on a metal plane may be given by a distance between periodically arranged holes and dielectric constants of a metal and a dielectric thin film.

However, when surface plasmon is used, there is a limitation in enhancing quantum efficiencies of QDIPs and QWIPs. Accordingly, there is a need for a novel structure capable of further enhancing quantum efficiency.

### SUMMARY

The present disclosure relates to improving quantum efficiency of an infrared photodetector having a quantum well structure or a quantum dot structure. A dielectric layer of benzocyclobutene (BCB) or a BCB/metal disk array layer is stacked on a perforated hole to improve the quantum efficiency.

An infrared photodetector according to an embodiment of the present disclosure includes a bottom contact layer, a light absorption layer stacked on the bottom contact layer, a top contact layer stacked on the light absorption layer, a metal layer stacked on the top contact layer to induce surface plasmon resonance and having a plurality of holes, and a dielectric layer stacked on the metal layer to satisfy an antireflection condition with respect to externally impinging light at a surface plasmon resonance frequency. The dielectric layer may be a benzocyclobutene (BCB) layer.

In an example embodiment, the infrared photodetector may further include a metal disk array (MDA) layer stacked on the dielectric layer.

In an example embodiment, the metal disk array (MDA) layer may be offset to be aligned with a hole of the metal layer.

In an example embodiment, the metal layer and the metal disk array (MDA) layer may each be made of gold.

In an example embodiment, the light absorption layer may include a plurality of active layers. The active layers may include a bottom AlGaAs layer disposed on the bottom contact layer, a bottom GaAs layer disposed on the bottom AlGaAs layer, a bottom InGaAs layer disposed on the bottom GaAs layer, an InAs quantum dot buried in the InGaAs layer, a top GaAs layer disposed on the InGaAs layer, and a top AlGaAs layer disposed on the top GaAs layer.

In an example embodiment, the infrared photodetector may further include a substrate, a GaAs buffer layer disposed on the substrate, and an AlAs layer disposed on the GaAs buffer layer. The AlAs layer may be disposed between the bottom contact layer and the GaAs buffer layer.

A method for manufacturing an infrared photodetector according to an embodiment of the present disclosure include forming a bottom contact layer on a substrate, forming a light absorption layer on the bottom contact layer, forming a top contact layer on the light absorption layer, forming a metal layer having a plurality of holes on the top contact layer to induce surface plasmon resonance, and forming a dielectric layer stacked on the metal layer to satisfy an antireflection condition with respect to externally impinging light at a surface plasmon resonance frequency. The dielectric layer may be formed of benzocyclobutene (BCB) by a spin-coating process.

In an example embodiment, the method may further include forming a metal disk array (MDA) layer stacked on the dielectric layer.

### BRIEF DESCRIPTION OF THE DRAWINGS

The present disclosure will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present disclosure.

FIG. 1 is a scanning electron microscope (SEM) image of a fabricated perforated metal film which illustrates an optical device according to an embodiment of the present disclosure.

FIG. 2 is a perspective view of an optical device according to an embodiment of the present disclosure and includes (a) that is a perspective view of a substrate/a perforated metal film (PMF), (b) that is a perspective view of a substrate/a perforated metal film (PMF)/a BCB layer, and (c) that is a photographed image of a substrate/a perforated metal film (PMF)/a BCB layer/MDA.

FIG. 3 illustrates a simulation result according to an embodiment of the present disclosure.

FIG. 4 is a cross-sectional view of an infrared (IR) photodetector according to an embodiment of the present disclosure.

FIG. 5 is a cross-sectional view of an infrared (IR) photodetector according to another embodiment of the present disclosure.

15

### DETAILED DESCRIPTION

Infrared (IR) detector imaging technologies have been widely used in industrial/military areas. The IR detector imaging technology requires a multi-functional IR detection sensor to determine a subject more precisely. Currently, a filter has been additionally used such that various wavelengths of a subject are selectively transmitted to detect wavelength-dependent distribution characteristics. Since such a structure occupies a large volume and must include a filter, it is not efficient. In recent years, methods using a surface plasmon resonance (SPR) structure in an infrared sensor to selectively transmit infrared without a filter are becoming more attractive. The SPR structure indicates selective transmission of a wavelength band and transmission amplification. A two-dimensional metal hole array (2D-MHA) structure was designed as a surface plasmon structure indicating an optical filter role and an optical amplification effect. Unlike when infrared transmits an existing flat substrate, the 2D-MHA structure exhibits a characteristic to cause a resonance phenomenon at a specific wavelength at the substrate interface. An antireflective condition (ARC) layer using a dielectric layer is formed by a deposition process. Impedance matching may be achieved by the ARC layer to amplify a transmission. When a dielectric layer is deposited to reduce reflection caused by impedance mismatching between two materials, the transmission may increase while an impedance value varies.

A silicon nitride (Si₃N₄) layer was deposited as an ARC layer on a 2D-MHA structure depending on thickness to measure a transmission, and an optimized thickness result exhibiting maximal amplification was obtained. However, a loss value of Si₃N₄ was large at an interesting infrared wavelength band and a plasma-enhanced chemical vapor deposition (PECVD) process was performed at high temperature between 450 and 550 degrees centigrade. Thus, the PECVD process may damage a device when the device is used as an application with an infrared device. In this regard, Benzocyclobutene (BCB) is proposed as an antireflective condition (ARC) material to replace Si₃N₄. As compared to Si₃N₄, a loss value of benzocyclobutene (BCB) is small at an interesting infrared wavelength band and the BCB is deposited by performing a spin-coating process at room temperature. In addition, the BCB is baked at temperature of about 250 degrees centigrade. However, such low temperature does not thermally damage an infrared device.

A metal disk array (MDA) structure on a dielectric layer (e.g., BCB) is proposed to exhibit a greater amplification factor through impedance matching, which is more effective than a method of amplifying a transmission by depositing only a dielectric layer. A metamaterial layer is formed, in which a dielectric layer and a patterned metal layer are combined with each other. The metamaterial layer is used as an antireflective condition (ARC) layer. When the amplitude and phase of an electromagnetic wave are adjusted using the metamaterial layer, optical efficiency of an infrared device may be improved.

The metamaterial is a virtual material having a periodical arrangement of meta-atom designed with a metal or a dielectric material. The metamaterial is an artificial material created to have electrical/optical properties that do not exist in the natural world. The metamaterial may provide an antireflective condition (ACR) effect.

According to an embodiment of the present disclosure, a surface plasmon resonance (SPR) structure of a metal layer and an underlying periodical two-dimensional metal arrangement may be integrated with a quantum dot (QD) infrared photodetector (QDIP). Accordingly, the metamaterial layer may allow incident light to be transferred to the underlying surface plasmon resonance structure and the infrared photodetector at a surface plasmon resonance wavelength without reflection of the incident light. Accordingly, the infrared photodetector may provide a selectivity at a resonance wavelength of the surface plasmon structure. That is, a metamaterial layer may be disposed on a metal thin film having a predetermined pitch designed with a specific surface plasmon resonance wavelength to minimize reflection of external incident light on the metal thin film at the surface plasmon resonance wavelength. Accordingly, a conventional QDIPs device may be designed to have a high spectral response at a specific wavelength, the specific wavelength may be selected as a surface plasmon resonance wavelength by the design of the metal thin film, and the surface plasmon resonance wavelength may be selected to specify properties of a metamaterial layer stacked on the metal thin film.

Although a typical semiconductor has a three-dimensional structure, a two-dimensional, one-dimensional or zero-dimensional structure may be fabricated. Since the two-dimensional, one-dimensional or zero-dimensional structure has quantum properties, the two-dimensional structure is called a quantum well (QW), the one-dimensional structure is called a quantum wire (QWi), and the zero-dimensional structure is called a quantum dot (QD). With high detectivity and low relative quantum efficiency, a quantum dot (QD) may maximize a response effect during integration of a surface plasmon resonance structure.

In particular, an infrared detector to which a quantum dot (QD) is applied (quantum-dot infrared detector) is a quantum-type infrared detector which has a high detectivity property and absorbs infrared to use indirect transition when optical current is generated. Therefore, the quantum-dot infrared detector has a relatively low quantum efficiency characteristic than a conventional infrared detector using direct transition such as HgCdTe, InSb or Type II superlattice.

According to an embodiment of the present disclosure, when a metamaterial layer/a surface plasmon resonance structure (metal screen thin film) are integrated into a QDIPs device, the response effect may be maximized. Thus, an optical device according to an embodiment of the present disclosure may be applied as an infrared image sensor.

An infrared photodetector may use a compound semiconductor (CS) quantum well structure. A representative compound semiconductor constituting a quantum dot and a quantum well is a III/V group semiconductor containing a III group material such as Ga, Al, and In and a V group material such as As, P, and Sb.

A photodetector according to an embodiment of the present disclosure may use a quantum well structure formed by stacking compounds in which (Ga, Al, In) and (As, P, Sb) are combined in two, three or four types. A quantum dot may be disposed in the quantum well structure. Specifically, an active region absorbing infrared may include an InAs quantum dot formed in an InGaAs layer.

According to an embodiment of the present disclosure, a metal layer having periodically arranged holes to induce a surface plasmon resonance effect and a metamaterial layer stacked on the metal layer may be formed on a conventional infrared photodetector. The metamaterial layer may include a dielectric layer of benzocyclobutene (BCB) and a metal disk array (MDA) on the dielectric layer.

The metal layer and a lower structure of the metal layer may induce a surface plasmon resonance and a sequentially stacked metal layer/dielectric layer/metal disk array structure may provide an antireflection condition to external incident light.

The surface plasmon resonance was achieved using a metal thin film having periodical holes. An early test of a periodical subwavelength hole array provided discovery of extraordinary optical transmission (EOT). The extraordinary optical transmission exceeds the prediction based on classical theory. Many studies for understanding the mechanism of the extraordinary optical transmission have been conducted to implement application products from sensors to optical components.

An infrared detector is an area to which a surface plasmon resonance may be applied and is used in a military detector, medical diagnosis, and environmental monitoring. The infrared detector provides a superior platform to prove performance of perforated metal films (PMF).

Over several years, a plurality of papers have reported the integration of a perforated metal film (PMF) or a metallic grating in an infrared detector.

According to the papers, coupling of light to an active region of an infrared detector was improved due to resonant excitation of surface plasmon polaritons (SPPs). The surface plasmon polaritons (SPPs) is known as the origin of transmission enhancement.

However, the resonance property of a perforated metal film (PMF) results in unwanted back-reflection caused by a great impedance mismatch.

One of the candidates to remedy the above drawback is that a dielectric layer (BCB)/a metal disk array (MDA) capable of performing impedance matching are inserted between two different media to suppress reflection. That is, the dielectric layer (BCB)/the MDA coated on a perforated metal film (PMF) may increase a transmission at an SPP resonance wavelength.

However, it is not clear to apply the standard antireflection theory based on interference of a plane wave to a resonance structure such as a perforated metal film (PMF) because a strongly localized electromagnetic field may violate the plane wave hypothesis. Therefore, a systematic study to determine an optimal structure of a dielectric layer/an MDA on a perforated metal film (PMF) was not conducted. That is, a transmission was not investigated while changing periodicity of the perforated metal film (PMF) and thickness of the dielectric layer.

According to an embodiment of the present disclosure, enhancement of transmission or suppression of reflection of a perforated metal film (PMF) was investigated at primary and secondary SPP resonance wavelengths in an infrared area by using a BCB layer/an MDA. The perforated metal film (PMF) employed a gold thin film and included a two-dimensional square array of a circular hole of subwavelength.

A simulation based on rigorous coupled wave analysis was used to check a resonance wavelength of the perforated metal film (PMF). A test result was that a transmission was enhanced by the BCB layer under a specific condition. In a structure used in the test, the PMF and the BCB layer were sequentially stacked on a GaAs substrate. A conventional lithography technique was applied to the PMF.

An analytical model based on a homogenized effective material was developed to investigate antireflection coating (ARC) between two dissimilar media which are composed of air and PMF/GaAs. In the analytical model, the PMF was considered a homogenized layer having resonance effective parameters (refractive index, impedance, dielectric constant, and permeability).

An effective impedance of a perforated metal film (PMF) was calculated, and an impedance matching condition required for antireflection coating in a resonance structure was found. The impedance matching condition is different from a conventional refraction coefficient matching condition for antireflection coating on a dielectric surface.

Preferred embodiments of the present disclosure will be described below in more detail with reference to the accompanying drawings. The present disclosure may, however, be embodied in different forms and should not be constructed as limited to the embodiments set forth herein. Rather, these embodiments are provided so that this disclosure will be thorough and complete, and will fully convey the scope of the present disclosure to those skilled in the art. Like numbers refer to like elements throughout.

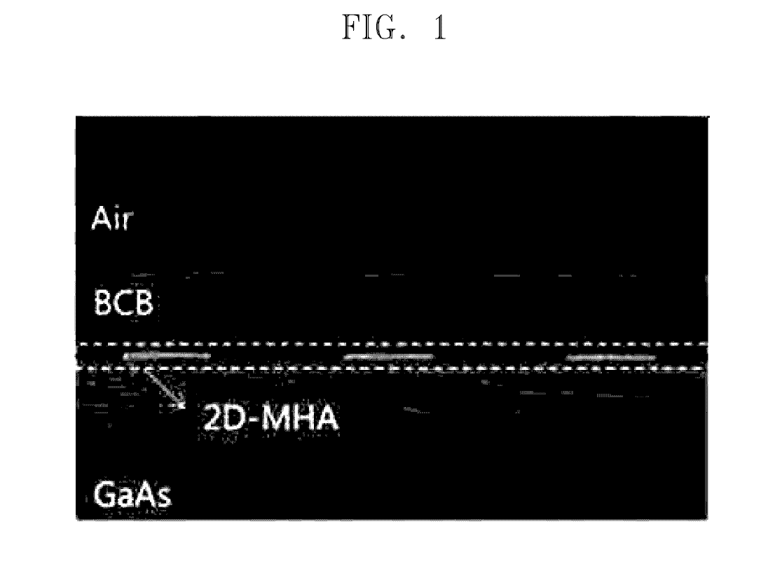

FIG. 1 is a scanning electron microscope (SEM) image of a fabricated perforated metal film which illustrates an optical device according to an embodiment of the present disclosure.

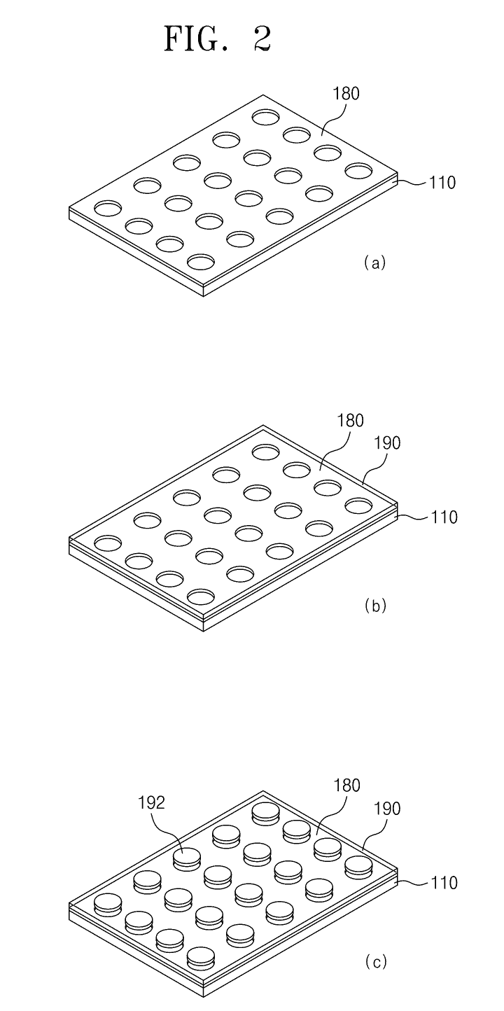

FIG. 2 is a perspective view of an optical device according to an embodiment of the present disclosure and includes (a) that is a perspective view of a substrate/a perforated metal film (PMF), (b) that is a perspective view of a substrate/a perforated metal film (PMF)/a BCB layer, and (c) that is a photographed image of a substrate/a perforated metal film (PMF)/a BCB layer/MDA.

Referring to FIGS. 1 and 2, a perforated metal film (PMF) includes a gold (Au) thin film having a circular hole of a 2D square arrangement on a GaAs substrate. On the other hand, a BCB layer is deposited on a PMF structure through a spin coating technique.

The perforated metal film (PMF) or a 2D metal hole array (MHA) may be fabricated through the steps (A) to (E). In the step (A), a hexamethyldisilazane (HMDS) is spin-coated on a GaAs substrate as an adhesive layer. The GaAs substrate may be a semi-insulating double-polished GaAs substrate. The HMDS is a material to enhance an adhesive force between a photoresist and the GaAs substrate. Then, a negative-0tone photoresist layer is spin-coated. In the step (B), a periodic circular post pattern is formed on the photoresist layer by a conventional photolithography process. In the step (C), a titanium (Ti) layer is deposited as an adhesive layer to a thickness of 5 nm and a gold (Au) layer is deposited to a thickness of 50 nm For example, the titanium (Ti) layer and the gold (Au) layer may be deposited through an electron-beam evaporator. Then, the photoresist layer is removed by a lift-off process. The lift-off process may use acetone. In the step (D), the perforated metal film (PMF) may be obtained after the lift-off process is performed. In the step (E), a BCB material is coated on the perforated metal film (PMF) through a spin coater and a baking process is performed at a temperature of about 250 degrees centigrade to obtain a BCB layer/PMF structure.

Due to the use of the semi-insulating double-polished GaAs substrate, a clearer transmission than that of a substrate may be measured. The 2D-MHA structure is formed by photolithography process, the benzocyclobutene (BCB) is deposited for different thickness, and a difference between transmissions with respect to BCB thickness is checked. Referring to an SEM image, the BCB is uniformly formed on the 2D-MHA structure.

A transmission is measured using an infrared spectrometer (FT-IR). A test value and a theoretical value may be compared using two theoretical methods.

First, an SPR structure of an infrared band is analyzed through a CST microwave studio using a finite difference time domain (FDTD) and by setting a test variable, a test error is minimized to estimate a result. In this case, thickness of BCB is only a variable. While varying the thickness of the BCB, optimized thickness at which a transmission is maximally amplified may be searched.

SPP resonance varies depending on a pitch (p). An SPP resonance wavelength may be expressed as below.

λ_{i, j}∝p·\sqrt{ε_{sub}^{′}/(i²+j²)} Equation (1)

In the Equation (1), i and j are integers and represent degrees of SPP resonance coupling and ε_{sub}^{′}represents a real part of a dielectric constant of a substrate. Primary and secondary SPP modes were observed at an Au—GaAs interface.

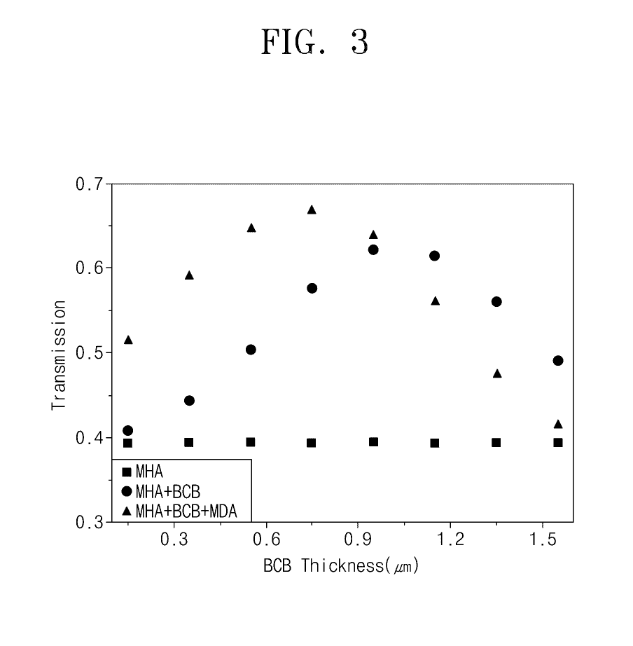

FIG. 3 illustrates a simulation result according to an embodiment of the present disclosure.

Referring to FIG. 3, a transmission depending on thickness of BCB was calculated at a wavelength corresponding to a primary SPP mode.

Squares indicate a result of a metal hole array (MHA) structure, circles indicate a result of an MHA/BCB structure, and triangles indicate a result of an MHA/BCB/MDA structure. In case of the MHA structure, a transmission rarely varies depending on thickness of a BCB layer. In case of the MHA/BCB structure, a transmission is maximal (˜0.61) near a thickness of about 0.95 μm. In case of the MHA/BCB/MDA structure, a transmission is maximal (˜0.66) near a thickness of about 0.75 μm.

When BCB is deposited on a 2D-MHA with a lattice distance of 1.8 μm, a result of simulation is that as compared to a transmission before deposition of the BCB, a transmission increases up to 58 percent to be highest.

After processing a metal disk array (MDA) structure, a result is that a transmission is higher when the thickness of the BCB is 0.75 μm than when thickness of the BCB is 0.95 μm. Since the BCB is used as a single antireflection coating (ARC) layer in a structure where BCB is deposited on the 2D-MHA, a transmission is high at a thickness of 0.95 μm. However, an optimal thickness of an MDA-stacked structure (metamaterial-ARC layer) is not an existing optimal thickness but 0.75 μm.

Next, a sandwich structure is modeled using a transfer matrix and a three-layer theory to determine whether an optimized BCB thickness is correctly found. The modeling is performed to find an optimized structure using characteristics that are exhibited at a boundary between air and the metamaterial-ARC layer and a boundary between the metamaterial-ARC layer and the 2D-MHA. Accordingly, a result may be experimentally and theoretically proved by comparing the test, the simulation, and the theory.

An infrared device according to an embodiment of the present disclosure may use a surface plasmon resonance structure to selectively perform optical amplification and an optical filtering at a wavelength of an infrared band. In addition, the infrared device may use a metamaterial-ACR layer, in which a dielectric layer and a patterned metal structure are combined, to obtain a result that a transmission is improved maximally by 72 percent or more at a specific wavelength band.

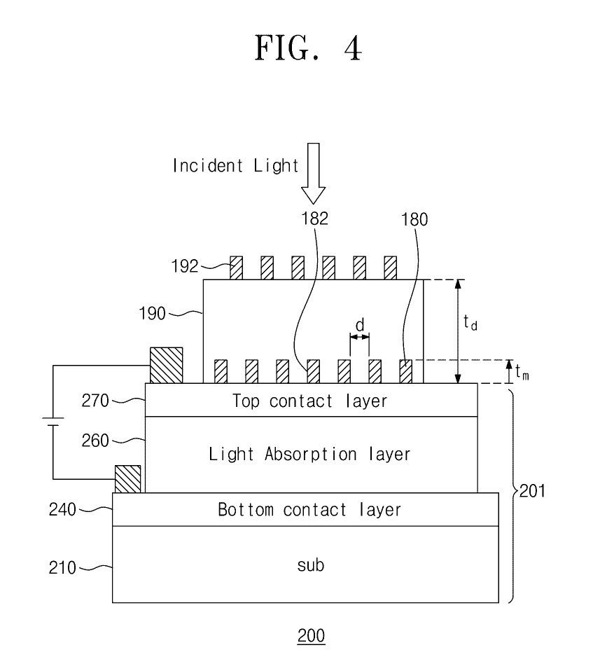

FIG. 4 is a cross-sectional view of an infrared (IR) photodetector 20 according to an embodiment of the present disclosure.

Referring to FIG. 4, the infrared photodetector 200 includes a bottom contact layer 240, a light absorption layer 260 stacked on the bottom contact layer 240, a top contact layer 270 stacked on the light absorption layer 260, a metal layer 180 stacked on the top contact layer 270 to induce surface plasmon resonance and include a plurality of holes, and a dielectric layer 190 stacked on the metal layer 180 to satisfy an antireflection condition with respect to externally impinging light at a surface plasmon resonance frequency. The dielectric layer 190 is a benzocyclobutene (BCB) layer. A metal disk array (MDA) layer 192 may be stacked on the dielectric layer 190. The MDA layer 192 may be slightly offset to be aligned with a hole 182 of the metal layer 180. A disk diameter of the MDA layer 192 may be substantially equal to that of the hole 182 of the metal layer 180.

A structure of the metal layer 180/the dielectric layer 190 is integrated on an infrared device 201. The infrared device 201 may include the substrate 210/the bottom contact layer 240/the light absorption layer 260/the top contact layer 270.

The substrate 210 may be dependent on a structure of the infrared device 201. Preferably, the infrared device 201 may be a quantum dot infrared photodetector (QDIP) device.

The substrate 210 may be a substrate for a photon detector. The substrate 210 may be a semi-insulated GaAs substrate. The bottom contact layer 240 may be a silicon-doped GaAs layer. The top contact layer 270 may be a silicon-doped GaAs layer. The light absorption layer 260 may be a quantum well structure or a quantum dot structure. In case of the quantum well structure, the light absorption layer 260 may be a multi-layered structure of GaAs/AlGaAs. In case of the quantum dot structure, a multi-layered structure of GaAs/AlGaAs may include a quantum dot of InAs.

The metal layer 180 may be a metal thin film. The metal layer 180 may have circular holes 182 two-dimensionally arranged in a matrix. The metal layer 180 may be a perforated metal film. The metal layer 180 may be about 50 nm, and a pitch between adjacent holes may be about 1.8 μm. A diameter of the hole may be half the pitch.

The metal layer 180 and the top contact layer 270 may induce surface plasmon resonance. A surface plasmon resonance wavelength may mainly depend on the pitch between holes and a hole shape. Thickness of the metal layer 180 may be small enough as compared to a wavelength of incident light.

More specifically, the surface plasmon resonance wavelength may match a maximum wavelength of spectral response of the underlying light absorption layer 260. Accordingly, the metal layer 180 may selectively amplify only the surface plasmon resonance wavelength and provide the amplified surface plasmon resonance wavelength to the light absorption layer 260. In this case, incident light impinging on the metal layer 180 may be wide-field infrared. However, the incident light may reflect incident light on the metal layer 180. Thus, an effect resulting from the surface plasmon resonance may be reduced.

The light impinging on the metal layer 180 needs to antireflectively transmit the metal layer 180 to maximally maintain the surface plasmon resonance effect. Thus, the dielectric layer 190 may be stacked on the metal layer 180. A refractive index and thickness of the dielectric layer 190 may be selected to satisfy an antireflection condition at the surface plasmon resonance wavelength. The dielectric layer 190 may be a benzocyclobutene (BCB) layer that is less absorbed in an infrared area. The BCB layer may be coated using a spin-coating technique and may be stabilized by a baking process.

Accordingly, the dielectric layer 190 may transfer the incident light to the metal layer 180 at the surface plasmon resonance wavelength without substantial reflection, and the metal layer 180 may induce the surface plasmon resonance to transfer energy of a surface plasmon resonance wavelength to the light absorption layer 260. The light absorption layer 260 may be optimized to produce maximum current at the surface plasmon resonance wavelength. Thus, reduction in low quantum efficiency of the quantum device may be overcome.

The dielectric layer 190 and the MDA layer 192 may be sequentially stacked on the metal layer 180. The dielectric layer 190 and the MDA layer 192 as a meta-material may be set to satisfy the antireflection condition. A wavelength at which a transmission of the metamaterial is high may be selected as a wavelength to maximize the surface plasmon resonance effect at the underlying metal layer 180. The MDA layer 192 may be formed by a lift-off process.

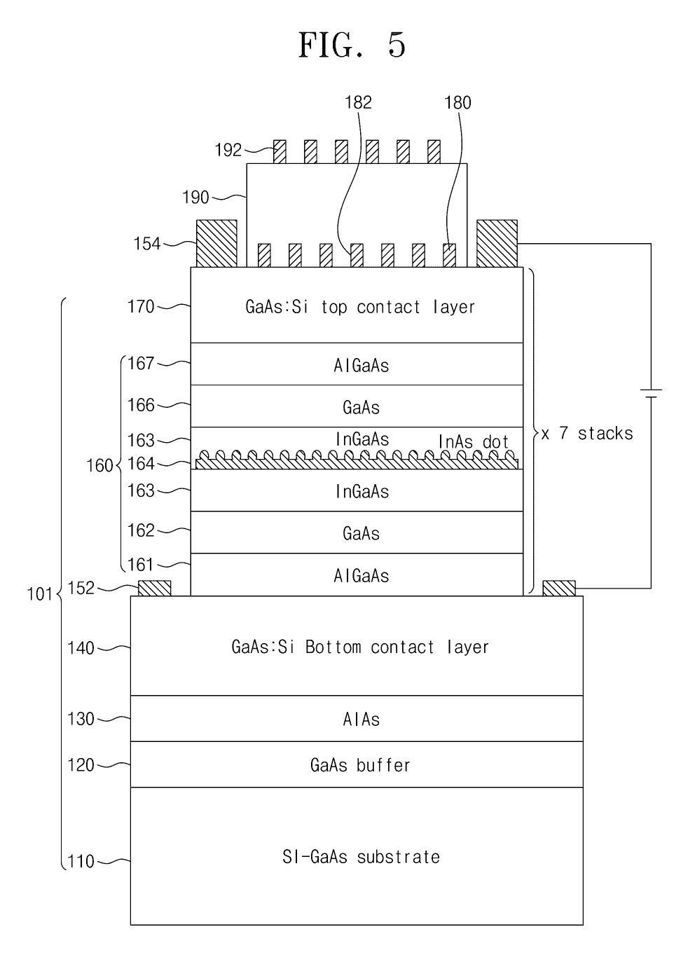

FIG. 5 is a cross-sectional view of an infrared (IR) photodetector 100 according to another embodiment of the present disclosure.

Referring to FIG. 5, the infrared photodetector 100 includes a bottom contact layer 140, a light absorption layer 160 stacked on the bottom contact layer 140, a top contact layer 170 stacked on the light absorption layer 160, a metal layer 180 stacked on the top contact layer 170 to induce surface plasmon resonance and having a plurality of holes, and a dielectric layer 190 stacked on the metal layer 180 to satisfy an antireflection condition with respect to externally impinging light at a surface plasmon resonance frequency. The dielectric layer 190 is a benzocyclobutene (BCB) layer. A metal disk array (MDA) layer 192 may be stacked on the dielectric layer 190. The MDA layer 192 may be slightly offset to be aligned with a hole 182 of the metal layer 180. A disk diameter of the MDA layer 192 may be substantially equal to that of the hole 182 of the metal layer 180.

A structure of the metal layer 180/the dielectric layer 190 may be integrated on an infrared device 101. The infrared device 101 may include a substrate 101/the bottom contact layer 140/the light absorption layer 160/the top contact layer 170.

The substrate 110 may be dependent on a structure of the infrared device 101. Preferably, the infrared device 101 may be a quantum dot infrared photodetector (QDIP) device.

The substrate 110 may be a substrate for a photon detector. The substrate 110 may be a semi-insulated GaAs substrate. The bottom contact layer 140 may be a silicon-doped GaAs layer. The top contact layer 170 may be a silicon-doped GaAs layer. A thickness of the substrate 110 may be about 350 μm.

A GaAs buffer layer 120 may be formed on the substrate 110. A thickness of the GaAs buffer layer 120 may be about 100 nm.

An AlAs layer 130 may be formed on the GaAs buffer layer 120. A thickness of the AlAs layer 130 may be about 50 nm.

A bottom contact layer 140 may be disposed on the AlAs layer 130.

The bottom contact layer 140 may be a silicon-doped GaAs layer. A silicon doping concentration may be 2×10¹⁸/cm³. A thickness of the bottom contact layer 130 may be about 600 nm. A bottom metal electrode 152 may be formed on the bottom contact layer 130. The bottom metal electrode 152 may be ohmically bonded to the bottom contact layer 140.

The light absorption layer 160 and the top contact layer 170 may be disposed on the bottom contact layer 140. The light absorption layer 160 may include a plurality of stacked active layers. The light absorption layer 160 may a seven-stacked active layer structure.

The active layers may include a bottom AlGaAs layer 161 disposed on the bottom contact layer 140, a bottom GaAs layer 162 disposed on the bottom AlGaAs layer 161, a bottom InGaAs layer 163 disposed on the bottom GaAs layer 162, an InAs quantum dot 164 buried in the InGaAs layer 163, a top GaAs layer 166 disposed on the InGaAs layer 163, and a top AlGaAs layer 167 disposed on the top GaAs layer 166.

The bottom AlGaAs layer 161 may be an Al_{0.07}Ga_{0.03}As layer and have a thickness of about 52 nm. The bottom GaAs layer 162 may have a thickness of 1 nm The bottom InGaAs layer 163 may be an In_{0.15}Ga_{0.85}As layer. The bottom InGaAs layer 163 may have a thickness of 1 nm.

The InAs quantum dot 164 may be buried in the InGaAs layer 163 having a thickness of several nanometers (nm). The InAs quantum dot grown in the Stranski-Krastanov (S-K) growth mode is monolayer-grown within about two monolayers in the early stage. When the InAs quantum dot is grown to have a greater thickness than the monolayer-grown thickness, the InAs quantum dot does not overcome a strain caused by lattice mismatch between heterojunctions to be grown three-dimensionally. By using this property, a self-organization quantum dot having zero-dimensional quantum confinement effect may be formed. The formed InAs quantum dot is allowed to form a quantum dot of a three-dimensional structure on an InAs wetting layer monolayer-grown in the early stage.

The top GaAs layer 166 may be formed on the InGaAs layer 163. The top GaAs layer 166 may have a thickness of about 1 nm The top AlGaAs layer 167 may be disposed on the top GaAs layer 166. The top AlGaAs layer 167 may be an Al_{0.07}Ga_{0.03}As layer and have a thickness of 52 nm The active layer may be stacked in seven stacks.

The top contact layer 170 may be disposed on the top AlGaAs layer 167. The top contact layer 170 may be a silicon-doped GaAs layer. The silicon doping concentration may be 2×10¹⁸/cm³. A thickness of the top contact layer 170 may be about 20 nm.

A top metal electrode 154 may be disposed on the top contact layer 170. The top metal electrode 154 may be ohmically bonded to the top contact layer 170. The bottom electrode layer 152 and the top electrode layer 154 may apply a voltage to the light absorption layer 160.

The metal layer 180/the dielectric layer 190 may be sequentially stacked in an area in which the top metal electrode 154 is not disposed. The metal layer 180 may be a metal thin film and have through-holes two-dimensionally arranged in a matrix. The metal layer 180 may be a perforated metal film. The metal layer 180 may have a thickness of 50 nm, and a pitch between adjacent holes may be about 1.8 μm. A diameter of the hole may be half the pitch.

The metal layer 180 and the top contact layer 170 may induce surface plasmon resonance. A surface plasmon resonance wavelength may mainly depend on the pitch between the holes.

More specifically, the surface plasmon resonance wavelength may match a maximum wavelength of spectral response of the underlying light absorption layer 160. Accordingly, the metal layer 180 may selectively amplify only the surface plasmon resonance wavelength and provide the amplified surface plasmon resonance wavelength to the light absorption layer 260. In this case, incident light impinging on the metal layer 180 may be wide-field infrared. However, the incident light may reflect incident light on the metal layer 180. Thus, an effect resulting from the surface plasmon resonance may be reduced.

The light impinging on the metal layer 180 needs to antireflectively transmit the metal layer 180 to maximally maintain the surface plasmon resonance effect. Thus, the dielectric layer 190 may be stacked on the metal layer 180. A refractive index and thickness of the dielectric layer 190 may be selected to satisfy an antireflection condition at the surface plasmon resonance wavelength. The dielectric layer 190 may be a benzocyclobutene (BCB) layer that is less absorbed in an infrared area. The BCB layer may be coated using a spin-coating technique and may be stabilized by a baking process.

Accordingly, the dielectric layer 190 may transfer the incident light to the metal layer 180 at the surface plasmon resonance wavelength without substantial reflection, and the metal layer 180 may induce the surface plasmon resonance to transfer energy of a surface plasmon resonance wavelength to the light absorption layer 160. The light absorption layer 160 may be optimized to produce maximum current at the surface plasmon resonance wavelength. Thus, reduction in low quantum efficiency of the quantum device may be overcome.

The dielectric layer 190 and the MDA layer 192 may be sequentially stacked on the metal layer 180. The dielectric layer 190 and the MDA layer 192 as a meta-material may be set to satisfy the antireflection condition. A wavelength at which a transmission of the metamaterial is high may be selected as a wavelength to maximize the surface plasmon resonance effect at the underlying metal layer 180. The MDA layer 192 may be formed by a lift-off process.

The light absorption layer 160 may be optimized to produce maximum current at the surface plasmon resonance wavelength. Thus, reduction in low quantum efficiency of the quantum device may be overcome.

According to embodiments of the present disclosure, a transmission may be improved using a benzocyclobutene (BCB) layer as a dielectric layer on a metal hole array structure. In addition, according to embodiments of the present disclosure, a transmission may be improved using a dielectric layer/a metal disk array as an antireflective coating layer on a metal hole array structure.

Although the present disclosure has been described in connection with the embodiment of the present disclosure illustrated in the accompanying drawings, it is not limited thereto. It will be apparent to those skilled in the art that various substitutions, modifications and changes may be made without departing from the scope and spirit of the present disclosure.

1. An infrared photodetector comprising:
a bottom contact layer;
a light absorption layer stacked on the bottom contact layer;
a top contact layer stacked on the light absorption layer;
a metal layer stacked on the top contact layer to induce surface plasmon resonance and comprising a plurality of holes;
a bottom metal electrode formed on the bottom contact layer to provide Ohmic contact;
a top metal electrode disposed on the top contact layer to provide Ohmic contact; and
a dielectric layer stacked on the metal layer to satisfy an antireflection condition with respect to externally impinging light at a surface plasmon resonance frequency,
wherein the dielectric layer is a benzocyclobutene (BCB) layer.

2. The infrared photodetector as set forth in claim 1, further comprising:
a metal disk array (MDA) layer stacked on the dielectric layer.

3. The infrared photodetector as set forth in claim 2, wherein the metal disk array (MDA) layer is offset to be aligned with a hole of the metal layer.

4. The infrared photodetector as set forth in claim 2, wherein the metal layer and the metal disk array (MDA) layer are each made of gold.

5. The infrared photodetector as set forth in claim 1, wherein the light absorption layer comprises a plurality of active layers, and the active layers comprises:
a bottom AlGaAs layer disposed on the bottom contact layer;
a bottom GaAs layer disposed on the bottom AIGaAs layer;
a bottom InGaAs layer disposed on the bottom GaAs layer;
an InAs quantum dot buried in the InGaAs layer;
a top GaAs layer disposed on the InGaAs layer; and
a top AlGaAs layer disposed on the top GaAs layer.

6. The infrared photodetector as set forth in claim 1, further comprising:
a substrate;
a GaAs buffer layer disposed on the substrate; and
an AlAs layer disposed on the GaAs buffer layer,
wherein the AlAs layer is disposed between the bottom contact layer and the GaAs buffer layer.

7. A method for manufacturing an infrared photodetector, comprising:
forming a bottom contact layer on a substrate;
forming a light absorption layer on the bottom contact layer;
forming a top contact layer on the light absorption layer;
forming a metal layer comprising a plurality of holes on the top contact layer to induce surface plasmon resonance; and
forming a dielectric layer stacked on the metal layer to satisfy an antireflection condition with respect to externally impinging light at a surface plasmon resonance frequency
forming a bottom metal electrode on the bottom contact layer to provide Ohmic contact; and
forming a top metal electrode on the top contact layer to provide Ohmic contact,
wherein the dielectric layer is formed of benzocyclobutene (BCB) by a spin-coating process.

8. The method as set forth in claim 7, further comprising:
forming a metal disk array (MDA) layer stacked on the dielectric layer.
